(19) United States
(12) Patent Application Publication
(10) Pub. No.: US 2017/0287965 A1
(43) Pub. Date: Oct. 5, 2017

(54) SEMICONDUCTOR DEVICE AND METHOD FOR FABRICATING THE SAME

(71) Applicant: Renesas Electronics Corporation, Tokyo (JP)

(72) Inventors: Koji IIZUKA, Ibaraki (JP); Fumitoshi TAKAHASHI, Ibaraki (JP)

(73) Assignee: Renesas Electronics Corporation, Tokyo (JP)

(21) Appl. No.: 15/462,963

(22) Filed: Mar. 20, 2017

(30) Foreign Application Priority Data
Mar. 29, 2016 (JP) 2016-066053

(51) Int. Cl. H01L 27/146; H01L 21/768; H01L 21/762

(52) U.S. Cl. CPC H01L 27/14636; H01L 27/1464; H01L 27/1463; H01L 27/14683; H01L 21/76224; H01L 21/76829; H01L 21/76802; H01L 27/14603; H01L 27/14643; H01L 27/14623; H01L 27/14621; H01L 27/14627

(57) ABSTRACT

The semiconductor device includes a semiconductor substrate having a main surface and a back surface, an device isolation film, formed over the main surface of the semiconductor substrate and having a first surface making contact with the main surface and a second surface opposed to the first surface, a plate electrode disposed over the device isolation film in contact with the second surface of the device isolation film, and a pad electrode disposed adjacent to the first surface of the device isolation film and making contact with the plate electrode.

The semiconductor substrate has a first opening that passes therethrough from the back surface to the main surface and exposes the device isolation film. The device isolation film has a second opening located in the first opening and exposes a part of the plate electrode. The pad electrode is formed in the second opening and extends over the first surface of the device isolation film.

### CROSS-REFERENCE TO RELATED APPLICATIONS

The disclosure of Japanese Patent Application No. 2016-066053 filed on Mar. 29, 2016 including the specification, drawings and abstract is incorporated herein by reference in its entirety.

### BACKGROUND

This invention relates to semiconductor devices and methods for fabricating the semiconductor devices, and can be suitably used for a semiconductor device including a solid-state imaging device and a method for fabricating the semiconductor device.

Development of solid-state imaging devices using a complementary metal oxide semiconductor (CMOS), or so-called CMOS image sensors, has been proceeding. The CMOS image sensors include a plurality of pixels each having a photodiode and a transfer transistor. A type of the CMOS image sensors is a backside illuminated image sensor that captures light from the backside of its semiconductor substrate and senses the light on the photodiode. The backside illuminated image sensor needs to have a pad electrode, which is an input/output terminal for transmitting and receiving electrical signals with an external device, adjacent to the back surface of the semiconductor substrate.

Japanese Unexamined Patent Application Publication No. 2015-57853 discloses a structure in which a bonding pad is formed in an opening that is formed in a semiconductor substrate from the back surface, and is coupled to a top metal layer of a device substrate.

Japanese Translation of PCT International Application Publication No. 2011-515843 discloses a structure in which an electrically conductive material is inlaid in a TSV hole that is formed in a wafer from the back surface, and is coupled to a contact plug formed adjacent to the main surface of the wafer.

Japanese Unexamined Patent Application Publication No. 2015-79960 discloses a structure in which a TSV passing through a substrate is coupled to a TSV landing pad formed adjacent to the main surface of the substrate.

### SUMMARY

The inventors of the present invention have studied backside illuminated image sensors and found the following problems. The backside illuminated image sensor under study by the inventors has photodiodes and transfer transistors composing pixels, and a number of peripheral transistors composing peripheral circuitry, adjacent to the main surface of the semiconductor substrate, but this is not well known. The transfer transistors and peripheral transistors used herein are metal insulator semiconductor field effect transistors (MISFET). These devices are coupled to one another via multiple interconnect layers (interconnects) stacked on top of each other over the devices, thereby making up pixels and logic circuits. The aforementioned pad electrode is disposed adjacent to the back surface of the semiconductor substrate and also in an opening passing through the semiconductor substrate. The opening passes through the semiconductor substrate and reaches an interconnect of the bottom layer (hereinafter, referred to as an interconnect M1). The interconnect M1 is used as an etch stopper to form the opening by dry etching. More specifically, the interconnect M1 is, for example, a laminated layer of a barrier film on the lower side and a copper film on the upper side, and the barrier film functions as the etch stopper.

However, the study by the inventors of the present invention has revealed that the barrier film does not fully function as an etch stopper. Specifically, the opening is formed also in the interconnect M1 during etching, thereby impairing the reliability of the semiconductor device. Increasing the thickness of the barrier film may be a measure to provide sufficient etch-stop function, but it increases the thickness of the entire interconnect M1. The increase in thickness of the interconnect M1 makes it difficult to provide finer patterning of the interconnect M1, and lowers the integration density. Since the interconnect M1 located in a lower layer has the minimum width and is arranged at the minimum pitch among the multiple interconnect layers in order to directly couple the devices, the increase in thickness of the interconnect M1 is highly disadvantageous.

Accordingly, improvement of the reliability of the semiconductor device is in demand.

The other problems and novel features of the present invention will become apparent from the following description in the present specification and the accompanying drawings.

According to an embodiment, the semiconductor device includes a semiconductor substrate having a main surface and a back surface, a first insulating film formed over the main surface of the semiconductor substrate and having a first surface making contact with the main surface and a second surface opposed to the first surface, a polysilicon film disposed over the first insulating film and making contact with the second surface of the first insulating film, and an electrode film disposed adjacent to the first surface of the first insulating film and making contact with the polysilicon film. The semiconductor substrate has a first opening passing therethrough from the back surface to the main surface and exposing the first insulating film. The first insulating film is located in the first opening, and has a second opening that exposes a part of the polysilicon film. The electrode film is formed in the first opening, and extends to the first surface of the first insulating film.

According to the embodiment, the reliability of the semiconductor device can be improved.

### BRIEF DESCRIPTION OF THE DRAWINGS

FIG. 1 is a circuit block diagram snowing an exemplary configuration of a semiconductor device according to an embodiment,

FIG. 2 is a circuit diagram showing an exemplary configuration of a pixel.

FIG. 3 is a plan view of a pixel of the semiconductor device according to the embodiment.

FIG. 4 is a plan view of a chip area where the semiconductor device of the embodiment is formed.

FIG. 5 is a plan view of a transistor formed in a peripheral circuit area of the semiconductor device of the embodiment.

FIG. 6 is a cross-sectional view of a relevant part of the semiconductor device of the embodiment.

FIG. 7 is a cross-sectional view of a relevant part of the semiconductor device of the embodiment.

FIG. 8 is a cross-sectional view taken along line C-C′ in FIG. 7.

FIG. 9 is a cross-sectional view taken along line D-D′ in FIG. 7.

FIG. 10 is a cross-sectional view of a relevant part of the semiconductor device according to the embodiment, in a fabricating step.

FIG. 11 is a cross-sectional view of a relevant part of the semiconductor device according to the embodiment, in a fabricating step subsequent to FIG. 10.

FIG. 12 is a cross-sectional view of a relevant part of the semiconductor device according to the embodiment, in a fabricating step subsequent to FIG. 11.

FIG. 13 is a cross-sectional view of a relevant part of the semiconductor device according to the embodiment, in a fabricating step subsequent to FIG. 12.

FIG. 14 is a cross-sectional view of a relevant part of the semiconductor device according to the embodiment, in a fabricating step subsequent to FIG. 13.

FIG. 15 is a cross-sectional view of a relevant part of the semiconductor device according to the embodiment, in a fabricating step subsequent to FIG. 14.

FIG. 16 is a cross-sectional view of a relevant part of the semiconductor device according to the embodiment, in a fabricating step subsequent to FIG. 15.

FIG. 17 is a cross-sectional view of a relevant part of the semiconductor device according to the embodiment, in a fabricating step subsequent to FIG. 16.

FIG. 18 is a plan view of a relevant part of a semiconductor device, which is the first variation of the semiconductor device in FIG. 7.

FIG. 19 is a plan view of a relevant part of the semiconductor device, which is the second variation of the semiconductor device in FIG. 7.

### DETAILED DESCRIPTION

In the following embodiment, if necessary for convenience, an embodiment will be divided into a plurality of sections or embodiments in the description; however, excepting the case that is particularly demonstrated, these are not independent of each other, but are in a relationship in which one is a variation (s) of part or all of the other, a detailed description, a supplementary description, or the like. Also, in the following embodiment, when the number of elements and the like (including the number, the numeric value, the quantity, the range, and the like) are cited, excepting the case that is particularly demonstrated, the case in which the embodiment is clearly limited in principle to the particular number, and the like, the embodiment is not limited to the particular number, but the number may be more than or less than the particular number. Additionally, in the following embodiment, the constituent, components (including component steps and the like) are not necessarily required, excepting the case that is particularly demonstrated, the case in which the components are clearly required in principle, and the like. Similarly, in the following embodiment, when contours, positional relationships, and the like of the constituent components are cited, excepting the case that is particularly demonstrated, the case in which the components are obviously inappropriate in principle, and the like, it is assumed that those substantially approximate to or analogous to the contours or the like are included. This is also applied to the numeric value and the range described above.

With reference to the drawings, an embodiment will be described below. In all the drawings to describe the embodiment, the same reference numerals are assigned to the components with the same functions, and explanations thereof will not be repeated. Also, in the following embodiment, explanations of the same or similar part will not be repeated in principle, unless otherwise needed.

Through the drawings used to describe the embodiment, some components are not hatched even in the cross-sections for the purpose of providing a clear view. On the contrary, hatch patterns may be applied to even plan views for the sake of clarity.

### Embodiment

With reference to the drawings, the structure and the fabricating steps of the semiconductor device according to the embodiment will be described below in detail. In the embodiment, a CMOS image sensor, which is a backside illuminated image sensor that receives light on the backside of the semiconductor substrate, will be described as an example of the semiconductor device.

### [Configuration of Semiconductor Device]

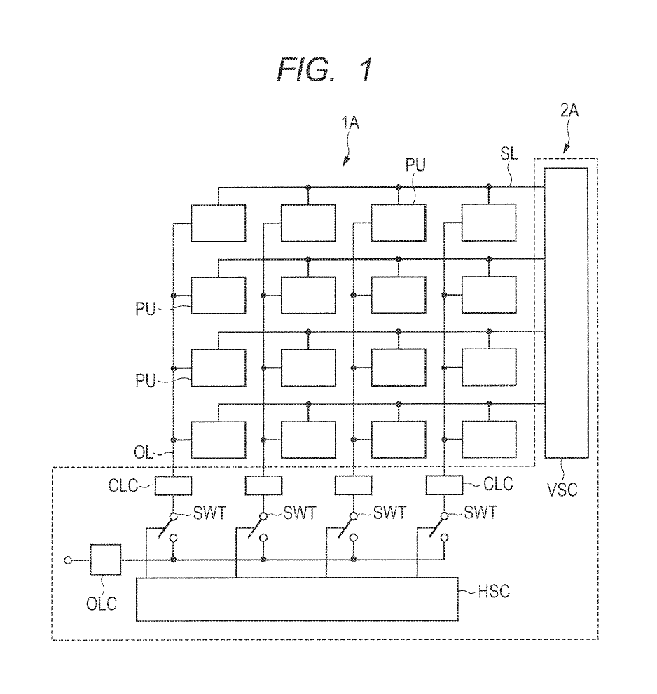

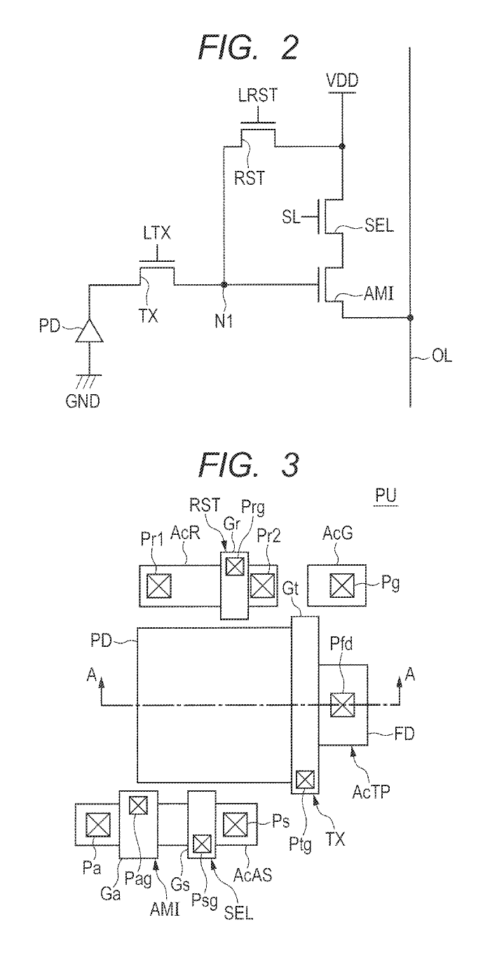

FIG. 1 is a circuit block diagram showing an exemplary configuration of the semiconductor device according to the embodiment. FIG. 2 is a circuit diagram showing an exemplary configuration of a pixel. Although FIG. 1 shows 16 pixels arranged in an array (matrix) with 4 rows and 4 columns (4×4), the number of pixels, columns, and rows can be changed to any numbers. For example, an actual electronic apparatus, such as a camera, uses several million pixels.

In a pixel area 1A shown in FIG. 1, a plurality of pixels PU are arranged in an array, and drive circuits including a vertical scanning circuit VSC and a horizontal scanning circuit HSC are arranged around the pixel area 1A. The pixels (cells or pixel units) PU are placed at points of intersection of select lines SL and output lines OL. The select lines SL are coupled to the vertical scanning circuit VSC, while the output lines OL are coupled to column circuits CLC on a one-on-one basis. The column circuits CLC are coupled to an output circuit OLC via switches SWT. Each switch SWT is coupled to the horizontal scanning circuit HSC and is controlled by the horizontal scanning circuit HSC. The vertical scanning circuit VSC, horizontal scanning circuit HSC, column circuits CLC, switches SWT, and output circuit OLC are peripheral circuits for the pixels PU, and are arranged in a peripheral circuit area 2A.

For example, an electrical signal read out from a pixel PU selected by the vertical scanning circuit VSC and horizontal scanning circuit HSC is output through the output line OL and output circuit OLC.

As shown in FIG. 2, each of the pixels PU includes, for example, a photodiode PD, and four transistors, RST, TX, SEL, and AMI, The transistors, RST, TX, SEL, AMI are all n-channel MISFETs. The transistor RST is a reset transistor, the transistor TX is a transfer transistor, the transistor SEL is a select transistor, and the transistor AMI is an amplifier transistor. The transfer transistor TX is to transfer charges produced by the photodiode PD. Other transistors or capacitative elements may be incorporated in addition to the above transistors. Connection forms of the transistors include various modifications and applications.

In the example circuit shown in FIG. 2, the photodiode PD and the transfer transistor TX are coupled to each other in series between a ground potential (first reference potential) GND and a node N1. The reset transistor RST is coupled between the node N1 and a power supply potential (power supply potential line, or second reference potential) VDD. The select transistor SEL and the amplifier transistor AMI are coupled to each other in series between the power supply potential VDD and the output line OL. The gate electrode of the amplifier transistor AMI is coupled to the node N1, The gate electrode of the reset transistor RST is coupled to a reset line LRST. The gate electrode of the select transistor SEL is coupled to a select line SL, while the gate electrode of the transfer transistor TX is coupled to a transfer line (second select line) LTX.

For example, the transfer line LTX and the reset line LRST are enabled (set to an H level) to turn on the transfer transistor TX and the reset transistor RST. Consequently, all charges are discharged from the photodiode PD, which will have become depleted. Subsequently, the transfer transistor TX is turned off.

For example, suppose a mechanical shutter of the electronic device, such as a camera, is opened after the above operation, the photodiode PD generates a charge from incident light and stores the charge therein while the shutter is open. In short, the photodiode PD receives incident light and generates charges from the incident light.

Next, after the shutter is closed, the reset line LRST is disabled (set to an L level) to turn off the reset transistor RST. Further, the select line SL and transfer line LTX are enabled (set to an H level) to turn on the select transistor SEL and transfer transistor TX. Thus, the charge generated by the photodiode PD is transferred to an end of the transfer transistor TX adjacent to the node N1 (corresponding to a floating diffusion FD, which will be described later). At this moment, the potential of the floating diffusion FD changes according to the charge transferred from the photodiode PD, The changed potential is amplified by the amplifier transistor AMI, and appears on the output line OL. The potential of the output line OL is converted to an electric signal (light receiving signal), which is read as an output signal from the output circuit OLC via the column circuit CLC and the switch SWT.

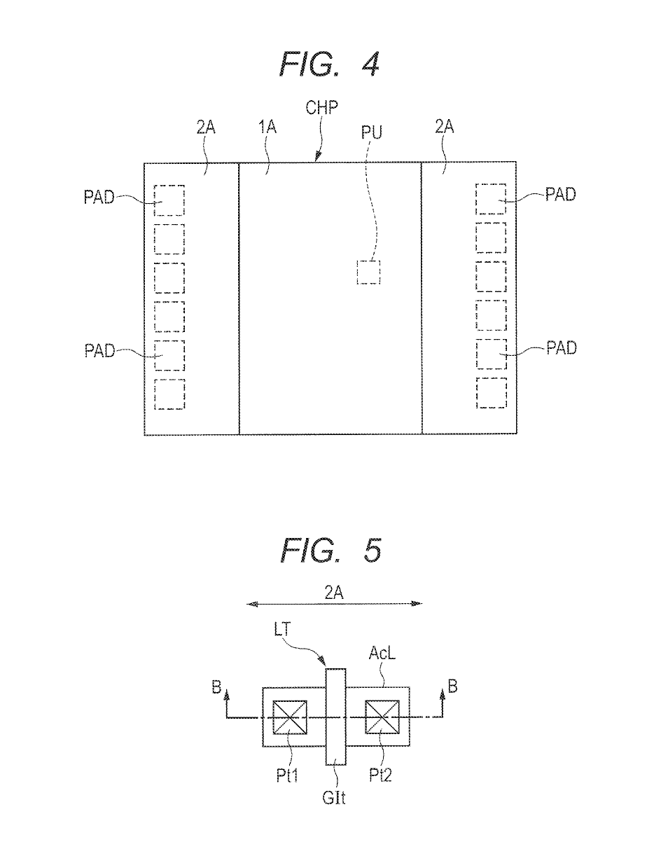

FIG. 3 is a plan view of a pixel of the semiconductor device in this

embodiment.

As shown in FIG. 3, a pixel PU (see FIG. 1) of the semiconductor device in this embodiment includes an active region AcTP in which the photodiode PD and the transfer transistor TX are disposed, and an active region AcR in which the reset transistor RST is disposed. The pixel PU also includes an active region AcAS in which the select transistor SEL and amplifier transistor AMI are disposed, and an active region AcG in which a plug electrode Pg, which is coupled to a ground potential line (not shown), is disposed.

In the active region AcR, a gate electrode Gr is disposed, and plug electrodes Pr1 and Pr2 are disposed respectively in source and drain regions positioned on both sides of the gate electrode Gr. The gate electrode Gr and the source and drain regions make up the reset transistor RST.

In the active region AcTP, a gate electrode Gt is disposed. In plan view, the photodiode PD is disposed on one of the sides of the gate electrode Gt, and the floating diffusion FD is disposed on the other side. The photodiode PD is a pn junction diode, and composed of, for example, a plurality of n-type or p-type impurity diffused regions (semiconductor regions). The floating diffusion FD functions as a charge storage portion or a floating diffusion layer, and is composed of, for example, an n-type impurity diffused region (semiconductor region), A plug electrode Pfd is disposed over the floating diffusion FD.

A gate electrode Ga and a gate electrode Gs are disposed in the active region AcAS. A plug electrode Pa is disposed at the end of the active region AcAS adjacent to the gate electrode Ga, and a plug electrode Ps is disposed at the other end of the active region AcAS adjacent to the gate electrode GS. On both sides of each of the gate electrodes Ga and Gs, the source and drain regions are positioned. The gate electrodes Ga, Gs and the source and drain regions make up the select transistor SEL and the amplifier transistor AMI that are coupled to each other in series.

A plug electrode Pg is disposed in an upper part of the active region AcG, This plug electrode Pg is coupled to a ground potential line (not shown), Thus, the active region AcG serves as a feeder region for applying a ground potential GND to a well region of the semiconductor substrate.

A plug electrode Prg, a plug electrode Ptg, a plug electrode Pag, and a plug electrode Psg are disposed, respectively, over the gate electrode Gr, the gate electrode Gt, the gate electrode Ga, and the gate electrode GS.

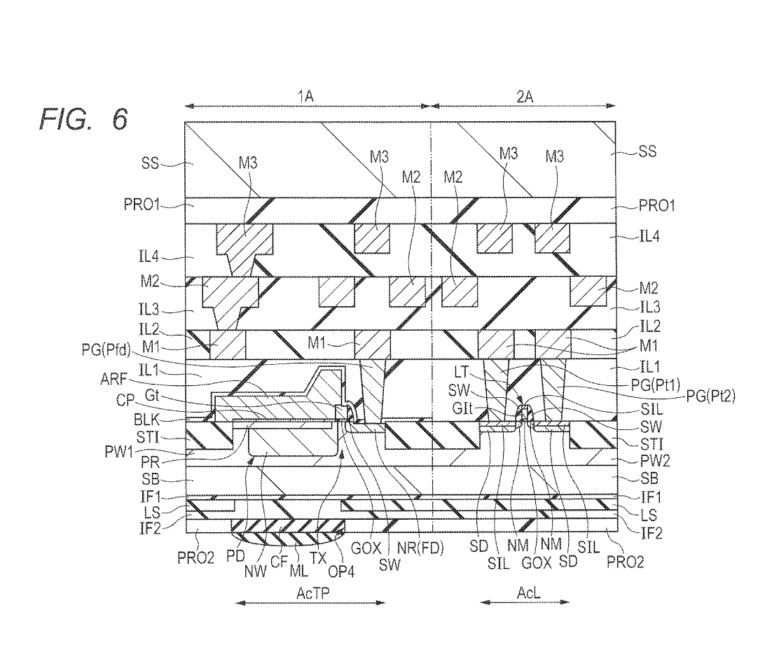

The aforementioned plug electrodes Pr1, Pr2, Pg, Pfd, Pa, Ps, Prg, Ptg, Pag, and Psg are coupled to one another where necessary, with a plurality of interconnect layers (e.g., interconnects M1 to M3, which will be described later, in FIG. 6). With the components described above, the circuits shown in FIGS. 1 and 2 can be formed.

FIG. 4 is a plan view showing a chip area where the semiconductor device according to the embodiment is formed. The chip area CHP includes a pixel area 1A and peripheral circuit areas 2A, and a plurality of pixels PU are arranged in a matrix in the pixel area 1A. In the peripheral circuit areas 2A, logic circuits are disposed. The logic circuits, for example, perform logic operation on output signals from the pixel area 1A, and output image data based on the operation results. The column circuits CLC, switches SWT, horizontal scanning circuit HSC, vertical scanning circuit VSC, and output circuit OLC shown in FIG. 1 are also disposed in the peripheral circuit areas 2A. In addition, a plurality of pad electrodes PAD, which are input/output terminals of the semiconductor device, are disposed in the peripheral circuit areas 2A. The pad electrodes PAD are electrically coupled to the logic circuits in the peripheral circuit areas 2A. Although it will be described later, in this embodiment, the devices making up the pixels PU and logic circuits are disposed adjacent to the main surface of the semiconductor substrate, while the pad electrodes PAD are disposed adjacent to the back surface of the semiconductor substrate.

FIG. 5 is a plan view showing a transistor formed in a peripheral circuit area of the semiconductor device according to the embodiment.

As shown in FIG. 5, a peripheral transistor LT, which is used for the logic circuit, is disposed in the peripheral circuit area 2A. In reality, a plurality of n-channel MISFETs and a plurality of p-channel MISFETs are formed as transistors making up the logic circuit in the peripheral circuit area 2A; however, FIG. 5 shows an n-channel MISFET, which is one of the transistors making up the logic circuit, as the peripheral transistor LT.

As shown in FIG. 5, an active region AcL is formed in the peripheral circuit area 2A, a gate electrode Glt of the peripheral transistor LT is disposed in the active region AcL, and source and drain regions of the peripheral transistor LT are formed, respectively, on the sides of the gate electrode Glt and within the active region AcL. Over the source and drain regions of the peripheral transistor LT, plug electrodes Pt1, Pt2 are disposed.

FIG. 5 shows only one peripheral transistor LT; however, in reality, a plurality of transistors are disposed in the peripheral circuit area 2A. The logical circuit can be configured by coupling the plug electrodes formed over the source and drain regions of the transistors, or the plug electrodes formed over the gate electrodes Glt with a plurality of interconnect layers (interconnects M1 to M3 which will be described later). The devices other than the MISFETs, for example, capacitative elements or transistors with another structure, may be sometimes incorporated in the logical circuit.

Following is a description about an example case where the peripheral transistor LT is an n-channel MISFET; however, the peripheral transistor LT can be a p-channel MISFET.

### [Device Structure in Pixel Area and Peripheral Circuit Area]

The structure of the semiconductor device according to the embodiment will be described. FIG. 6 is a cross-sectional view of a relevant part of the semiconductor device according to the embodiment. FIG. 6 is a cross-sectional view showing a relevant part of the pixel area 1A and peripheral circuit area 2A, and corresponds to the cross-sectional view taken along line A-A in FIG. 3 and the cross-sectional view taken along line B-B in FIG. 5,

As shown in FIG. 6, a photodiode PD and a transfer transistor TX are formed in the active region AcTP in the pixel area 1A of the semiconductor substrate SB. The photodiode PD is composed of a p-type well PW1, an n-type semiconductor region (n-type well) NW, and a p⁺-type semiconductor region PR, all formed in the semiconductor substrate SB, adjacent to the main surface of the semiconductor substrate SB. A peripheral transistor LT is formed in the active region AcL in the peripheral circuit area 2A of the semiconductor substrate SB.

The semiconductor substrate SB is a semiconductor substrate (semiconductor wafer) made of, for example, an n-type monocrystalline silicon doped with an n-type impurity (donor), such as phosphorus (P) or arsenic (As). In an alternative embodiment, the semiconductor substrate SB can be a so-called epitaxial wafer. If an epitaxial wafer is used as the semiconductor substrate SB, the semiconductor substrate SB can be formed by, for example, growing an epitaxial layer made of n⁻-type monocrystalline silicon doped with an n-type impurity (e.g., phosphorus (P) ) over the main surface of an n⁺-type monocrystalline silicon substrate doped with an n-type impurity (e.g., arsenic (As)). In this embodiment, the semiconductor substrate SB has a thickness from 600 to 700 μm before polishing, and is polished (thinned) to approximately 2 to 3 μm.

A device isolation film (device isolation region) STI made of an insulating material is disposed around the active region AcTP. The areas of the semiconductor substrate SB surrounded by the device isolation film STI are exposed, and the exposed areas are the active region AcTP and active region AcL.

The semiconductor substrate SB includes p-type wells (p-type semiconductor regions) PW1, PW2 formed from the main surface so as to have a predetermined depth. The p-type well PW1 is formed across the entire active region AcTP. Specifically, the p-type well PW1 is formed across the region where the photodiode PD is formed and the region where the transfer transistor TX is formed. On the other hand, the p-type well PW2 is formed across the entire active region AcL. Specifically, the p-type well PW2 is formed in a region where the peripheral transistor LT is formed. Both of the p-type well PW1 and p-type well PW2 are p-type semiconductor-regions doped with a p-type impurity, such as boron (B). The p-type well PW1 and p-type well PW2 are isolated from each other and also are electrically isolated from each other. In this description, the main surface of the semiconductor substrate SB denotes an upper surface of the semiconductor substrate in the active regions, while denoting an interface between the semiconductor substrate SB and device isolation film STI in the device isolation regions. However, the main surface may be sometimes referred to as the upper surface of the semiconductor substrate in the active regions and the upper surface of the device isolation film STI without specific reasons.

As shown in FIG. 6, an n-type semiconductor region (n-type well) NW is formed so as to be enclosed with the p-type well PWL of the semiconductor substrate SB in the active region AcTP. The n-type semiconductor region NW is an n-type semiconductor region doped with an n-type impurity, such as phosphorus (P) or arsenic (As).

The n-type semiconductor region NW is not only the n-type semiconductor region forming the photodiode PD, but also the source region of the transfer transistor TX. The n-type semiconductor region NW is mainly present in a region where the photodiode PD is formed; however, the n-type semiconductor region NW partially overlaps the gate electrode Gt of the transfer transistor TX in plan view. The depth (to the bottom surface) of the n-type semiconductor region NW is lesser than the depth (to the bottom surface) of the p-type well PW1. The gate electrode Gt is a conductive film made of a polysilicon film.

A p⁺-type semiconductor region PR is formed in a part of the surface of the n-type well NW. The p⁺-type semiconductor region PR is a p⁺-type semiconductor region doped with a p-type impurity, such as boron (B), in high concentration. The concentration of the impurity in the p⁺-type semiconductor region PR (p-type impurity concentration) is higher than that of the p-type well PW1 (p-type impurity concentration). Accordingly, the conductivity (electrical conductivity) of the p⁺-type semiconductor region PR is higher than the conductivity (electrical conductivity) of the p-type well PW1.

The depth (to the bottom surface) of the p⁺-type semiconductor region PR is lesser than the depth (to the bottom surface) of the n-type semiconductor region NW. The p⁺-type semiconductor region PR is mainly formed in the outermost layer part (surface part) of the n-type semiconductor region NW. As seen in the thickness direction of the semiconductor substrate SB, the n-type semiconductor region NW is present under the p⁺-type semiconductor region PR, which is the top layer, and the p-type well PW1 is present under the n-type semiconductor region NW.

The p⁺-type semiconductor region PR has a portion under which the n-type semiconductor region NW is not formed, and the part makes contact with the p-type well PW1. In other words, the p⁺-type semiconductor region PR has a portion where the n-type semiconductor region NW is present immediately thereunder and makes contact therewith, and a portion where the p-type well PW1 is present immediately thereunder and makes contact therewith.

The p-type well PW1 and n-type semiconductor region NW form a PN junction therebetween. The p⁺-type semiconductor region PR and n-type semiconductor region NW also form a PN junction therebetween. The p-type well PW1 (p-type semiconductor region), n-type semiconductor region NW, and p⁺-type semiconductor region PR make up the photodiode (PN junction diode) PD.

The photodiode PD is a light-receiving element. The photodiode PD can be also regarded as a photoelectric conversion element. The photodiode PD has functions of converting incident light into electricity to generate a charge and storing the generated charge, while the transfer transistor TX serves as a switch to transfer the charge stored in the photodiode PD from the photodiode PD.

The gate electrode Gt is formed so as to overlap a part of the n-type semiconductor region NW in plan view. The gate electrode Gt, which is the gate electrode of the transfer transistor TX, is formed (disposed) over the semiconductor substrate SB with an insulating film GOX interposed therebetween. On a sidewall of the gate electrode Gt formed is a sidewall spacer SW serving as a sidewall insulating film.

In the semiconductor substrate SB (p-type well PW1) in the active region AcTP, the n-type semiconductor region NW is formed on one of the sides of the gate electrode Gt, and an n-type semiconductor region NR is formed on the other side. The n-type semiconductor region NR is an n⁺-type semiconductor region doped with an n-type impurity, such as phosphorus (P) or arsenic (As), in high concentration, and the n-type semiconductor region NR is formed in the p-type well PW1, The n-type semiconductor region NR is a semiconductor region serving as a floating diffusion (layer) FD, and also serves as the drain region of the transfer transistor TX.

The n-type semiconductor region NR functions as the drain region of the transfer transistor TX, but can be also regarded as a floating diffusion (layer) FD. In addition, the n-type semiconductor region NW is a component making up the photodiode PD, but can also function as a semiconductor region used as the source of the transfer transistor TX. In other words, the source region of the transfer transistor TX is formed of the n-type semiconductor region NW, Thus, the n-type semiconductor region NW and gate electrode Gt preferably establish a positional relationship in which a part (on the source side) of the gate electrode Gt overlaps a part of the n-type semiconductor region NW in plan view. The n-type semiconductor region NW and n-type semiconductor region NR are formed apart from each other with a channel formation region of the transfer transistor TX (corresponding to a substrate region immediately under the gate electrode Gt) interposed therebetween.

A cap insulating film CAP is formed over the surface of the photodiode PD (see FIG. 3), that is a surface of the n-type semiconductor region NW and the p⁺-type semiconductor region PR. The cap insulating film CA is formed to keep the good surface properties, or good interface properties, of the semiconductor substrate SB. A reflection preventing film ARF is formed over the cap insulating film CA. Specifically, the reflection preventing film ARF is formed over the n-type semiconductor region NW and p⁺-type semiconductor region PR with the cap insulating film CP interposed therebetween. A part (end part) of the reflection preventing film ARF can cover the gate electrode Gt. The reflection preventing film ARF is not always essential, and therefore can be omitted.

As shown in FIG. 6, a gate electrode Glt of the peripheral transistor LT is formed over the p-type well PW2 in the active region AcL with a gate insulating film GOX interposed therebetween, and sidewall spacers SW are formed on opposite sidewalls of the gate electrode Glt. The source and drain regions of the peripheral transistor LTI are formed in the p-type well PW2 present on both sides of the gate electrode Glt. The source and drain regions of the peripheral transistor LT employ a lightly doped drain (LDD) structure, and include n⁻-type semiconductor regions NM, which are n-type lowly-doped semiconductor regions, and n⁺-type semiconductor regions SD, which are n-type highly-doped semiconductor regions. In addition, metal silicide films SIL are formed over surfaces of the gate electrode Glt of the peripheral transistor LT and the n⁺-type semiconductor regions SD that form the source and drain regions. On the other hand, the metal silicide layer SIL is not formed over the floating diffusion FD forming the drain region of the transfer transistor TX included in the pixel PU. Therefore, the surface of the floating diffusion FD is covered with a silicide block film BLK. The silicide block film BLK is, for example, a silicon oxide film. In this embodiment, the pixel area 1A is entirely covered with the silicide block film BLK. However, the reason for covering with the silicide block film BLK is to prevent formation of the metal silicide layer SIL on the floating diffusion FD of the transfer transistor TX, and therefore there is no need to form the silicide block film BLK on the other area. The gate electrode Glt is a conductive film made of a polysilicon film with a thickness of 150 to 200 nm.

An interlayer insulating film IL1 is formed over the semiconductor substrate SB so as to cover the gate electrode Gt, reflection preventing film ARF, and gate electrode Glt. The interlayer insulating film IL1 is formed over the entire main surface of the semiconductor substrate SB in the pixel area 1A and peripheral circuit area 2A. As described above, the surfaces of the gate electrode Gt, reflection preventing film ARF, and floating diffusion FD are covered with the silicide block film BLK in the pixel area 1A, and therefore, the interlayer insulating film IL1 is formed over the silicide block film BLK.

The interlayer insulating film IL1 is, for example, a silicon oxide film containing tetraethyl orthosilicate (TEOS) as a raw material. Conductive plug electrodes PG, including the aforementioned plug electrodes Pr1, Pr2, Pg, Pfd, Pa, Ps, Prg, Ptg, Pag, Psg, Pt1, Pt2, are inlaid in the interlayer insulating film IL1, For example, as shown in FIG, 6, a plug electrode Pfd, serving as a plug electrodes PG, is formed over the n-type semiconductor region NR serving as the floating diffusion FD. The plug electrode Pfd passes through the interlayer insulating film IL1 and reaches the n-type semiconductor region NR to electrically couple to the n-type semiconductor region NR.

The conductive plug electrodes PG, such as the plug electrodes Pr1, Pr2, Pg, Pfd, Pa, Ps, Prg, Ptg, Pag, Psg, Pt1, Pt2, are made by, for example, inlaying a barrier conductive film and a tungsten film formed over the barrier conductive film in a contact hole formed in the interlayer insulating film IL1. The barrier conductive film is, for example, a laminated film composed of a titanium film and a titanium nitride film formed over the titanium film (i.e., a titanium/titanium nitride film).

Over the interlayer insulating film IL1 with the plug electrodes PG (Pr1, Pr2, Pg, Pfd, Pa, Ps, Prg, Ptg, Pag, Psg, Pt1, Pt2) inlaid therein, for example, an interlayer insulating film IL2 is formed. Interconnects M1 are formed in the interlayer insulating film IL2.

The interlayer insulating film IL2 is, for example, a silicon oxide film, but is not limited to this, and can be made of a low dielectric constant film whose dielectric constant is lower than that of the silicon oxide film. An example of the low dialectic constant film is a SiOC film.

The interconnect M1 is, for example, a copper interconnect, and can be formed by a damascene method. The interconnect M1 is not limited to the copper interconnect, and can be also an aluminum interconnect. If the interconnect M1 is an inlaid copper interconnect (damascene copper interconnect), the inlaid copper interconnect is inlaid in an interconnect trench formed in the interlayer insulating film IL1, while if the interconnect M1 is an aluminum interconnect, the aluminum interconnect is formed by patterning a conductive film formed over the interlayer insulating film.

Over the interlayer insulating film IL2 in which the interconnects M1 are formed, an interlayer insulating film IL3, which is, for example, a silicon oxide film or a low dielectric constant film, is formed, and interconnects M2 are formed in the interlayer insulating film IL3. Over the interlayer insulating film IL3 in which the interconnects M2 are formed, an interlayer insulating film IL4 is formed, and interconnects M3 are formed in the interlayer insulating film IL4. The interconnects M2 and M3 are, for example, copper interconnects formed by a dual-damascene method, and have an interconnecting portion and a coupling portion making contact with the underlying interconnect, those portions being made in one piece. This embodiment shows three interconnect layers as an example; however, more interconnect layers can be added. The top interconnect layer, which is the interconnects M3 in this embodiment, are covered with a protective film PRO1, and a support substrate SS is attached to the protective film PRO1. The protective film PRO1 is, for example, a laminated film of a silicon oxide film and a silicon nitride film. The support substrate SS is, for example, a silicon substrate having a thickness of, for example, 600 to 700 jam.

The backside illuminated CMOS image sensor of this embodiment has a color filter CF and a microlens ML, as shown in FIG. 6, adjacent to the back surface of the semiconductor substrate SB that has been thinned to 2 to 3 μm.

In the pixel area 1A, an insulating film IF1 is formed so as to cover the entire back surface of the semiconductor substrate SB, and a light shielding film LS is formed over the insulating film IF1. The light shielding film LS has an opening OP1 to expose an area where the photodiode PD is present, but entirely covers the other areas. An insulating film IF2 and a protective film PRO2 are formed over the back surface of the semiconductor substrate SB so as to cover the insulating film IF1 and light shielding film LS, and the protective film PRO2 has an opening OP4 aligned with the opening OP1 of the light shielding film LS. The opening OP4 has a diameter greater than that of the opening OP1 to expose the entire opening OP1. The color filter CF and microlens ML are formed within the opening OP4 of the protective film PRO2. The insulating film IF1 is provided to reduce the dark current noise, and is made of, for example, HfxOy, TaxOy, AlxOy, ZrxOy or TixOy (x+y=1 in any compounds). The light shielding film LS is, for example, an aluminum film or tungsten film, and prevents light from entering any areas except for the area where the photodiode PD has been formed. The insulating film IF2 is a reflection preventing film made from, for example, a silicon oxide film of 0.1 to 0.2 μm in thickness. The protective film PRO2 is, for example, a silicon nitride film.

In the peripheral circuit area 2A, the insulating film IF1, light shielding film LS, insulating film IF2, and protective film PRO2 are also formed in this order over the back surface of the semiconductor substrate SB.

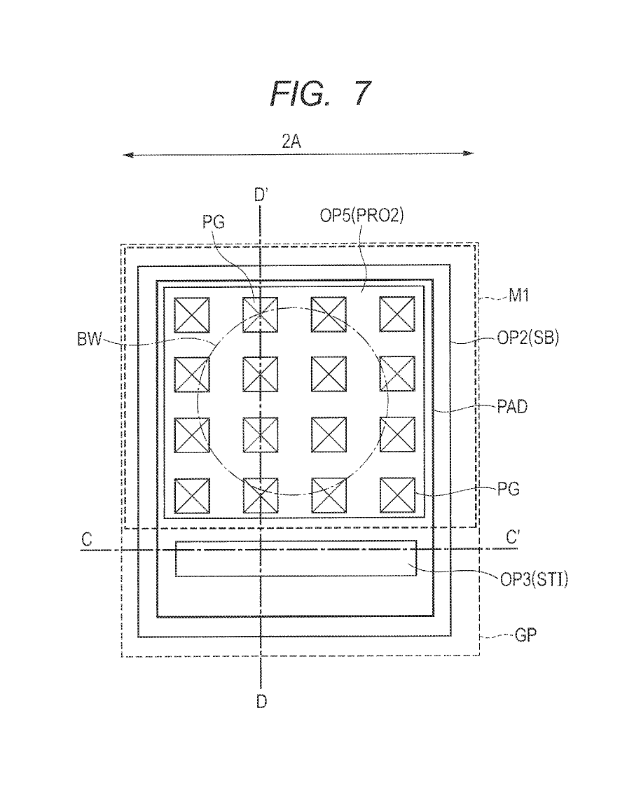

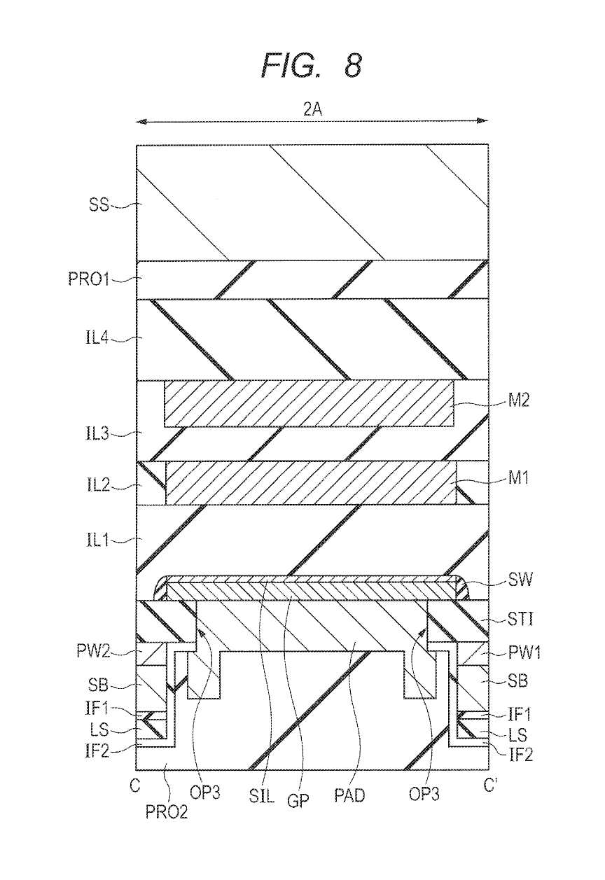

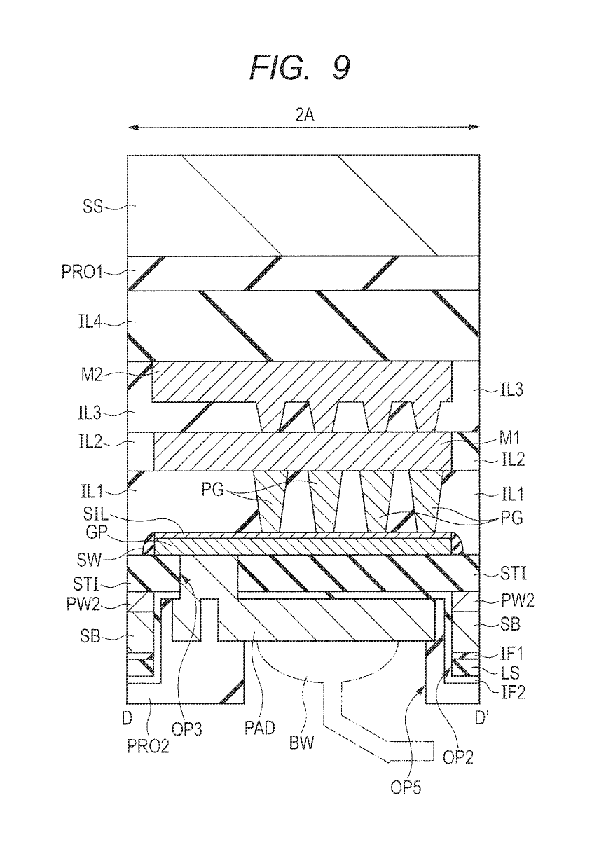

Next, a description will be made about a pad electrode PAD formed adjacent to the back surface of the semiconductor substrate SB in the peripheral circuit area 2A. FIG. 7 is a cross-sectional view of a relevant part of the semiconductor device according to the embodiment. More specifically, FIG. 7 is a plan view of a pad electrode. FIG. 8 is a cross-sectional view taken along line C-C′ in FIG. 7. FIG. 9 is a cross-sectional view taken along line D-D′ in FIG. 7. As shown in FIGS. 7 to 9, the pad electrode PAD is formed inside an opening OP2 formed in the back surface of the semiconductor substrate SB. The opening OP2 passing through the semiconductor substrate SB from the back surface of the semiconductor substrate SB reaches the device isolation film STI. The pad electrode PAD is formed over the back surface of the device isolation film STI with an insulating film IF2 interposed therebetween. Note that the main surface of the device isolation film STI denotes a surface adjacent to the interconnects M1 and M2, and the back surface denotes a surface adjacent to the semiconductor substrate SB. Over the main surface of the device isolation, film STI formed is a plate electrode GP to which the pad electrode PAD is coupled through an opening OP3 formed in the device isolation film STI. The pad electrode PAD has a laminated structure composed of a barrier conductive film and a main conductive film. The barrier conductive film is, for example, a titanium nitride film or a tungsten nitride film, and the main conductive film is, for example, an aluminum film (including an aluminum, film containing Si or Cu). The barrier conductive film is 20 to 30 nm in thickness, and the main conductor film is 600 to 1000 nm in thickness. The barrier conductive film is located adjacent to the plate electrode GP and makes contact with the plate electrode GP. The plate electrode GP is made of a conductive film (polysilicon film) with a thickness of 150 to 200 nm, which is the same layer as the gate electrodes Gt and Glt, and a silicide layer SIL is formed over the upper surface of the plate electrode GP. A sidewall spacer is further formed around (over the sidewalls of) the laminated structure composed of the plate electrode GP and silicide layer SIL. The plate electrode GP can be a non-doped polysilicon film, which is not doped with any impurity.

As described above, the pad electrode PAD is coupled to the plate electrode GP, which is disposed in contact with the main surface of the device isolation film STI, through the opening OP3 formed in the device isolation film STI in addition to the opening OP2 formed in the semiconductor substrate SB, thereby reducing the depth of the opening OP3, and improving the coupling reliability between the pad electrode PAD and plate electrode GP. Moreover, the pad electrode PAD is coupled to the plate electrode GP, but is not directly coupled to the interconnect M1, thereby making the interconnect M1 thinner and finer, and enhancing the integration density of the semiconductor device.

The interconnect. M1 disposed above the plate electrode GP is coupled to the plate electrodes GP via the plug electrodes PG and silicide layer SIL. The interconnect M2 disposed above the interconnect M1 is coupled to the interconnect M1. The interconnect M1 or M2 disposed above the plate electrode GP is coupled to the peripheral transistor LT included in a peripheral circuit. Thus, the pad electrode PAD is coupled to the peripheral transistor LT. If the plate electrode GP is extended to couple to the peripheral transistor LT, the interconnects M1 and M2 become unnecessary; however, a preferable way of coupling the pad electrode PAD to the peripheral transistor LT is using the interconnect M1 or/and M2.

The pad electrode PAD is covered with the protective film PRO2, but is partially exposed from an opening OP5 formed in the protective film PRO2. The exposed area of the pad electrode PAD from the protective film PRO2 is coupled to a bonding wire BW. Specifically, the exposed area of the pad electrode PAD from the opening OP5 is a coupling area to which the bonding wire BW is coupled. As shown in FIGS. 7 and 9, the coupling area (in other words, the interior part of the opening OP5) is entirely positioned over the back surface of the device isolation film STI, but positioned outside of the opening OP3 formed in the device isolation film STI, and does not overlap the opening OP3. Since the opening OP3 is entirely covered with the protective film PRO2, an upper part of the opening OP3 cannot serve as a coupling area. The opening OP3 creates a recess at the top surface of the pad electrode PAD, but the recess is filled with the protective film PRO2, and therefore is not exposed from the protective film PRO2. The pad electrode PAD extends along the flat back surface of the device isolation film STI, and the coupling area is present over the back surface of the device isolation film STI. This positional relationship among the openings OP2, OP3, and OP5 can improve the coupling reliability between the bonding wire BW and pad electrode PAD. In addition, the device isolation film STI having high mechanical strength is used as a base where wire bonding is provided, thereby improving the coupling reliability of the bonding wire BW.

As shown in FIGS. 7 and 9, the plug electrodes PG are disposed apart from the opening OP3 of the device isolation film STI, thereby improving the coupling reliability between the pad electrode PAD and plate electrode GP.

In addition, as shown in FIGS. 7 and 9, aligning the area where the plug electrodes PG are disposed with the opening OP5 of the protective film PRO2 in the thickness direction can reduce the chip area.

As shown in FIG. 9, coupling the bonding wire BW with the pad electrode PAD at a deep position in the opening OP2 of the semiconductor substrate SB can keep the ball part of the bonding wire BW nearly flush with the back surface of the semiconductor substrate SB, thereby reducing the package height.

### [Fabricating Method of Semiconductor Device]

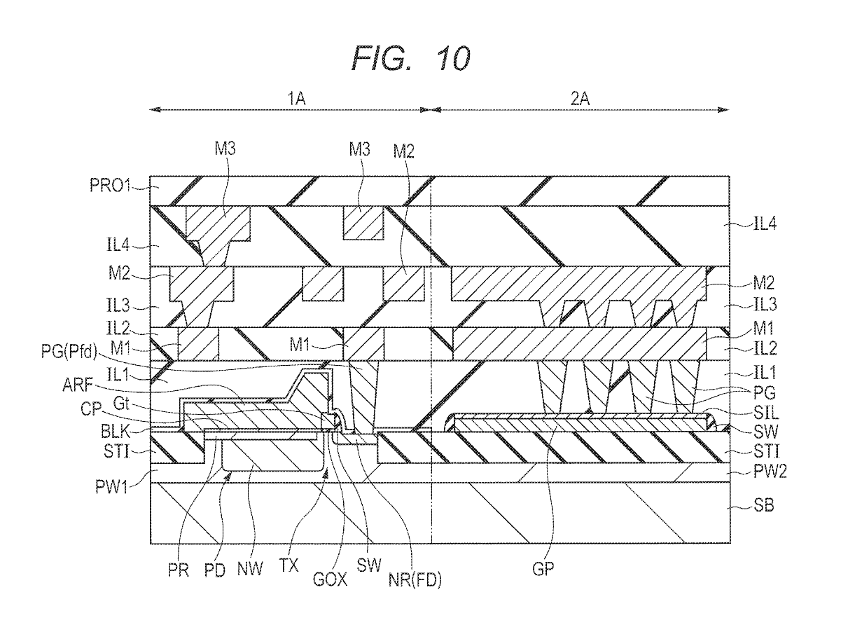

A method for fabricating the semiconductor device according to the embodiment will be described. FIGS. 10 to 17 are cross-sectional views of a relevant part of the semiconductor device according to the embodiment, in the course of fabricating steps. FIGS. 10 to 17 show the pixel area 1A and peripheral circuit area 2A. The left side of FIG. 10 corresponds to the left side of the cross-sectional view of FIG. 6. The peripheral circuit area 2 A in FIG. 10 is a cross-sectional view taken along line D-D′ in FIG. 7 corresponding to FIG. 9.

Firstly, a “step of preparing a semiconductor wafer” is performed. A semiconductor substrate SB (semiconductor wafer) with semiconductor elements formed thereover as shown in FIG. 10 is prepared. As described above with reference to FIG. 6, a photodiode PD, a transfer transistor TX, and a plurality of interconnects M1, M2, and M3 are formed in the pixel area 1A, and the upper part of the interconnects M3 are covered with a protective film PRO1. As described above with reference to FIG. 9, a plate electrode GP is formed over a device isolation film STI, a silicide layer SIL is formed over the plate electrode GP, and sidewall spacers SW are formed over the sidewalls of the plate electrode GP and silicide layer SIL, in the peripheral circuit area 2A. In addition, the interconnects M1 and M2 are disposed over the plate electrode GP, and the interconnect M1 is coupled to the plate electrode GP via the plug electrodes PG, while the interconnect M2 is coupled to the interconnect M1. Although not shown in FIG. 10, a peripheral transistor LT shown in FIG. 6 is also formed in the peripheral circuit area 2A.

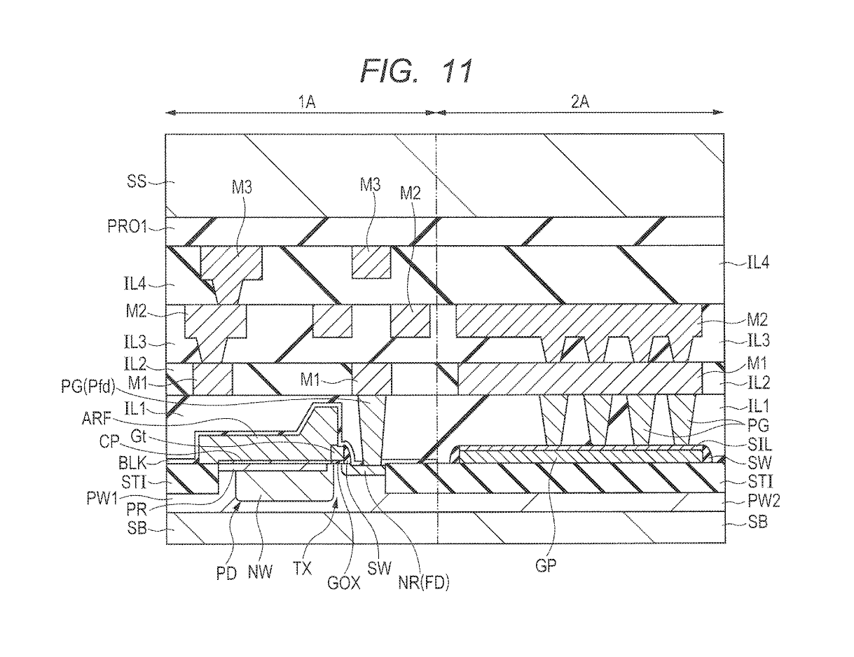

Next, a “step of thinning the semiconductor substrate SB” is performed. As shown in FIG. 11, a support substrate SS is attached over the protective film PRO1, and then the semiconductor substrate SB is polished on the back surface to be thinner. The support substrate SS is, for example, a silicon substrate having a thickness of 600 to 800 μm. The semiconductor substrate SB is thinned from its original thickness of 600 to 800 μm to a thickness of 2 to μm.

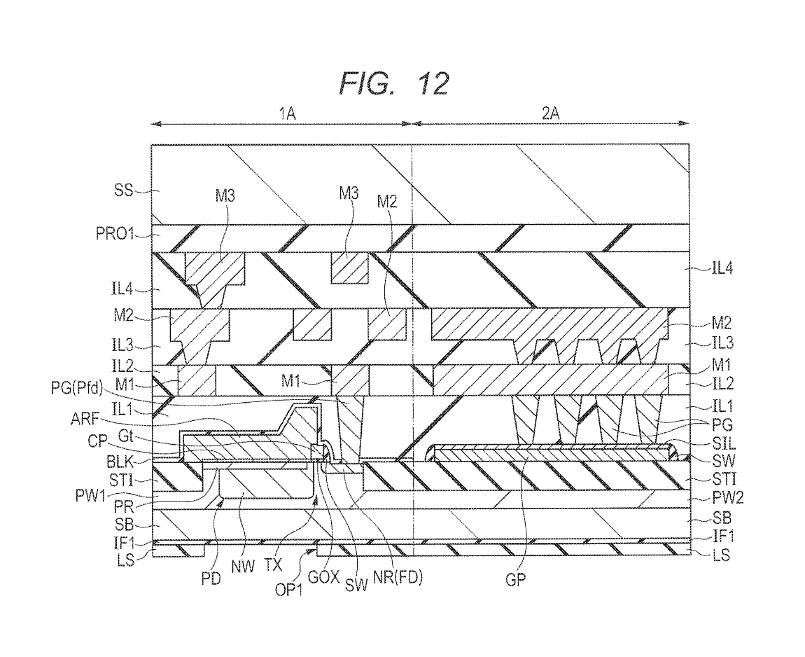

Next, a “step of forming a light shielding film LS” is performed. As shown in FIG. 12, an insulating film IF1 is firstly formed over the back surface of the semiconductor substrate SB to cover the back surface of the semiconductor substrate SB in the pixel area 1A and peripheral circuit area 2A with the insulating film IF1. For the insulating film IF1, for example, HfxOy, TaxOy, AlxOy, ZrxOy or TixOy (x+y=1 in any compounds) can be used. Then, a light shielding film LS is formed over the insulating film IF1 so as to cover the back surface of the semiconductor substrate SB in the pixel area 1A and peripheral circuit area 2A. However, the light shielding film LS has an opening OP1 to expose the area where the photodiode PD is formed. The light shielding film LS is an aluminum film or a tungsten film whose thickness is approximately 0.2 μm.

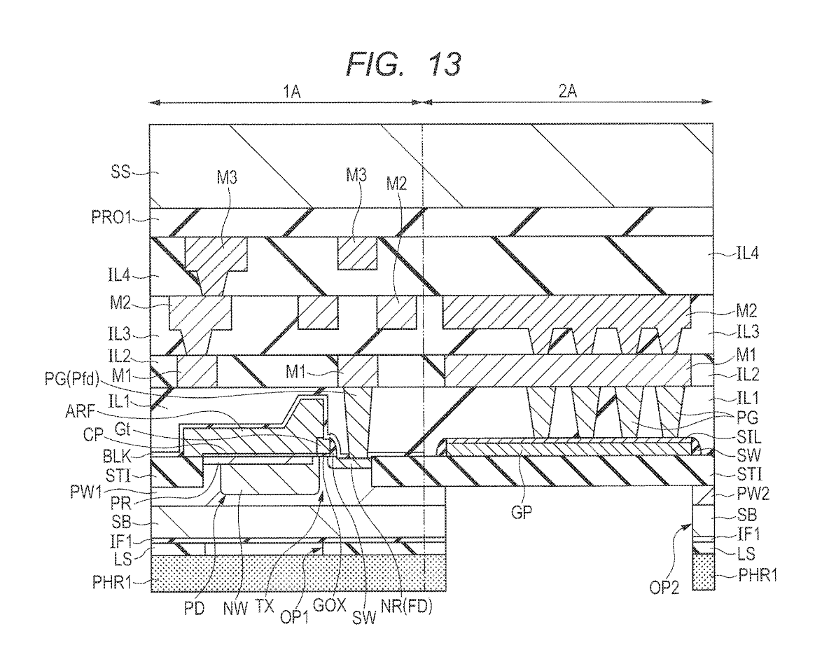

Next, a “step of forming an opening OP2” is performed. As shown in FIG. 13, the semiconductor substrate SB is dry-etched using, for example, a photoresist film PHR1 as a mask to form an opening OP2 in the semiconductor substrate SB in the peripheral circuit area 2A. As shown in FIG. 7, the opening OP2 is formed on the inside of the plate electrode GP so as to overlap with the plate electrode GP. Thus, the back surface of the device isolation film STI in the peripheral circuit area 2A is exposed. The device isolation film STI functions as an etch stopper during the dry etching process performed on the semiconductor substrate SB. In the dry etching process, the pixel area 1A is covered with the photoresist film PHR1. After the dry etching process, the photoresist film PHR1 present in the pixel area 1A and peripheral circuit area 2A is removed.

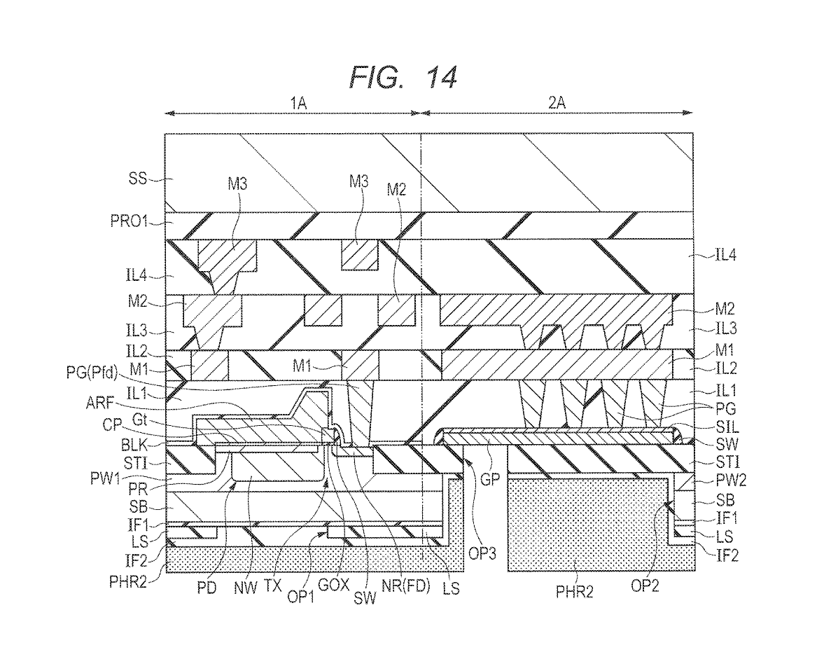

Next, a “step of forming an opening OP5” is performed. As shown in FIG. 14, firstly, an insulating film IF2 is deposited over the back surface of the semiconductor substrate SB so as to cover the light shielding film LS. Subsequently, the insulating film IF2 and device isolation film STI are dry-etched using, for example, a photoresist film PHR2 as a mask to form an opening OP3 in the insulating film IF2 and device isolation film STI in the peripheral circuit area 2A, thereby exposing the back surface of the plate electrode GP. As shown in FIG. 7, the opening OP3 is located inside the opening OP2 and overlaps with the plate electrode GP. In the dry etching process, the polysilicon film making up the plate electrode GP functions as an etch stopper. Since the dry etching is performed on condition that the etching rate of the polysilicon film is lower than that of the silicon oxide filmmaking up the device isolation film STI, the amount of etched (overetched) plate electrode GP (polysilicon film) during formation of the opening OP3 in the device isolation film STI can be reduced. In addition, since the plate electrode GP makes contact with the main surface of the device isolation film STI, the depth of the opening OP5 can be made shallow, thereby reducing the amount of etched plate electrode GP. Incidentally, the thickness of the device isolation film STI is approximately 0.3 μm, as is the opening OP3. After the dry etching process, the photoresist film PHR2 present in the pixel area 1A and peripheral circuit area 2A is removed.

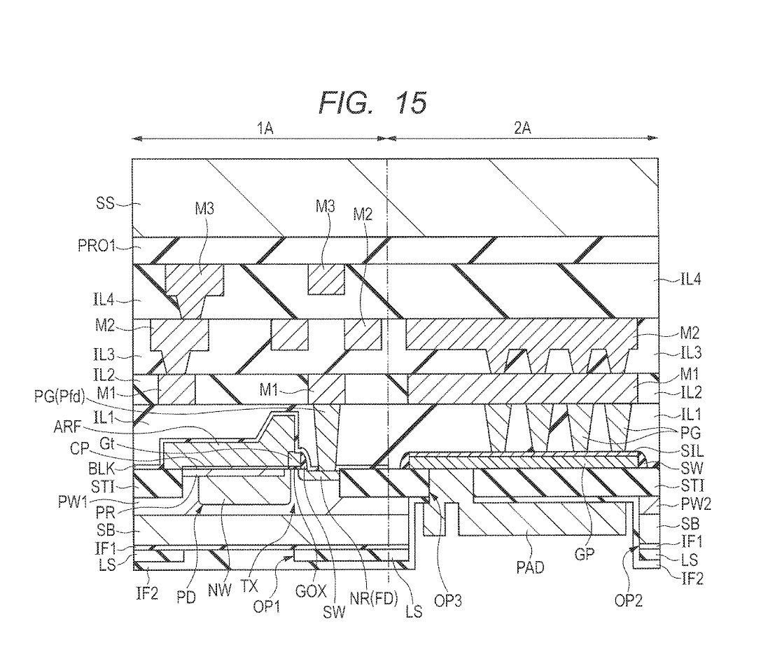

Next, a “step of forming a pad electrode PAD” is performed. As shown in FIG. 15, after a barrier conductive film and aluminum film are sequentially deposited over the back surface of the semiconductor substrate SB, a pad electrode PAD is formed by patterning the aluminum film and barrier film sequentially using a well-known photolithography technique and dry etching technique. As shown in FIG. 7, the whole pad electrode PAD fits in the opening OP2. The lower surface of the pad electrode PAD is positioned at a higher level than the back surface of the semiconductor substrate SB. Specifically, the pad electrode PAD is inlaid in the semiconductor substrate SB in the thickness direction. The pad electrode PAD is also present in the opening OP3 formed in the device isolation film STI to couple to the plate electrode GP.

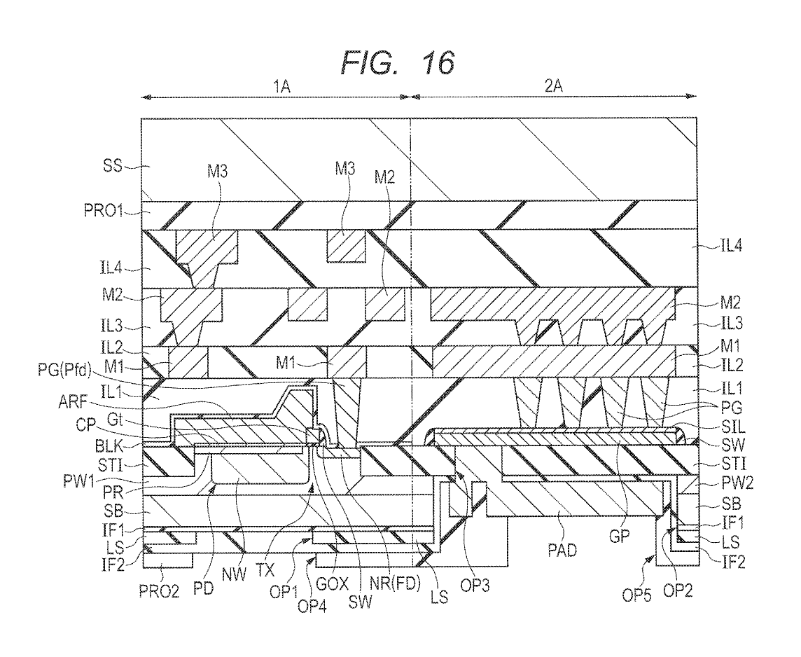

Next, a “step of forming a protective film PRO2” is performed. As shown in FIG. 16, a protective film PRO2, which is, for example, a silicon nitride film, is deposited over the back surface of the semiconductor substrate SB, and then an opening OP4 and an opening OP5 are formed in the protective film PRO2 using a well-known photolithography technique and dry-etching technique. The opening OP4 having a diameter larger than the opening OP1 exposes the opening OP1 entirely. As also shown in FIG. 7, the opening OP5 exposes the pad electrode PAD partially, but is located outside the opening OP3 so as not to overlap with the opening OP3. The protective film PRO2 may be a light-sensitive polyimide film.

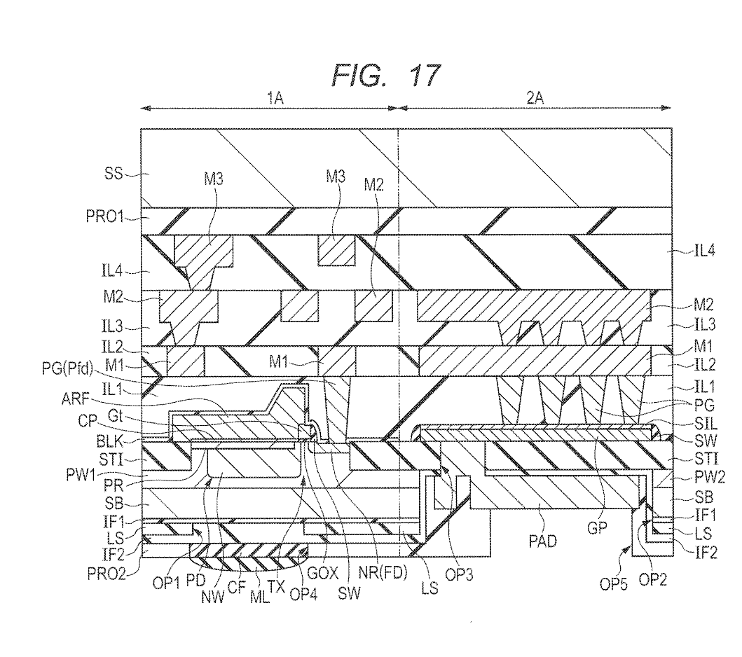

Next, a “step of forming a color filter OF and a microlens ML” is performed. As shown in FIG. 17, a color filter CF and a microlens ML are formed in the opening OP4 formed in the protective film PRO2.

Finally, the semiconductor device according to the embodiment is completed as shown in FIG. 9, through a “step of coupling a bonding wire BW” to couple the bonding wire BW to a surface of the pad electrode PAD in the opening OP5 formed in the protective film PRO2.

Although the openings OP4 and OP5 are formed in the protective film PRO2 in the same step; however, this is lust an example, and the opening OP5 can be formed after the color filter CF and microlens ML are formed as described later. In other words, only the opening OP4 is formed in the “step of forming a protective film PRO2”, and the opening OP5 is formed in the protective film PRO2 after the “step of forming a color filter CF and a microlens ML”. According to this fabricating method, residues that may be left inside the opening OP5 during the “step of forming a color filter CF and a microlens ML” can be prevented, thereby eliminating the risk of damage to the pad electrode PAD.

According to the fabricating method of this embodiment, the plate electrode GP made of a polysilicon film is used as an etch stopper for forming the opening OP3 in the device isolation film STI. This can prevent the opening OP3 from piercing through the etch stopper during the etching process. Therefore, this can improve the reliability of the semiconductor device. In addition, the plate electrode GP made of a polysilicon film, which is the same layer as the gate electrodes Gt and Glt, is used as an etch stopper, and therefore there is no need to make the interconnect M1 thicker, thereby making the semiconductor device finer.

In the first etching process to form the opening OP2 in the semiconductor substrate SB, the device isolation film STI is used as an etch stopper, while in the second etching process to form the opening OP3 in the device isolation film STI, the plate electrode GP is used as an etch stopper. The device isolation film STI (and insulating film IF2) subjected to the second etching process is relatively thinner than the semiconductor substrate SB, and therefore the amount of the etch stopper to be etched can be reduced. Furthermore, since the plate electrode GP serving as an etch stopper makes contact with the device isolation film STI, the thickness of the film to be etched can be less in comparison with the case where the interconnect M1 is used as an etch stopper. Therefore, the amount of etched plate electrode GP, which is an etch stopper, can be reduced.

### First Modification

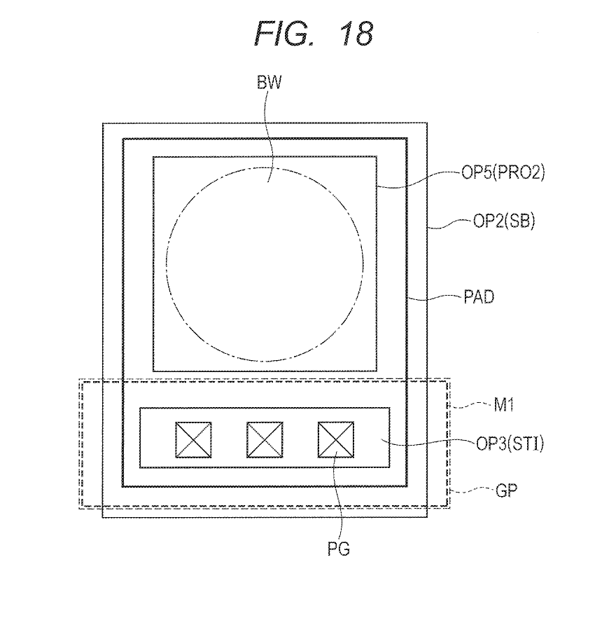

The first modification is made to the pad electrode PAD shown in FIG. 7. FIG. 18 is a plan view of a semiconductor device modified from the original in FIG. 7. In FIG. 18, components corresponding to those in the above-described embodiment are denoted by like numerals.

As shown in FIG. 18, the plate electrode GP and interconnect M1 are disposed outside the opening OP5, and are designed to be smaller in plan size in comparison with the plate electrode GP and interconnect M1 in the aforementioned embodiment. Therefore, an interconnect M that is not coupled to the pad electrode PAD can be disposed so as to overlap the opening OP5.

### Second Modification

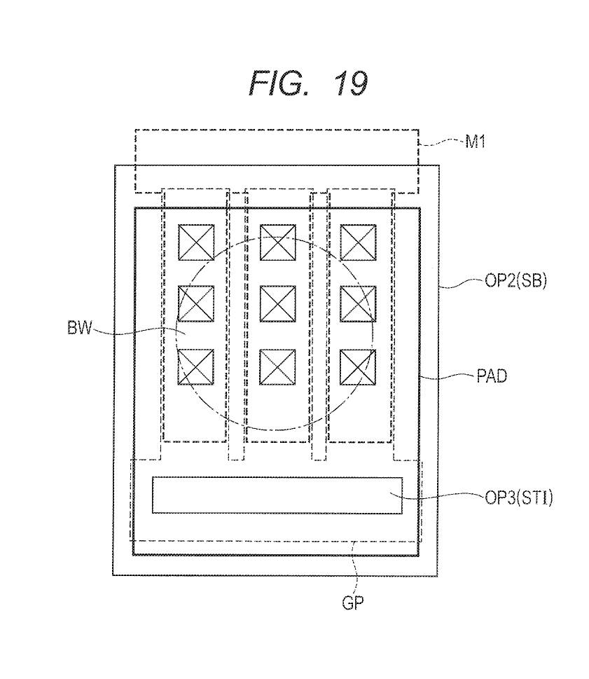

The second modification is made to the pad electrode PAD shown in FIG. 7. FIG. 19 is a plan view of a semiconductor device modified from the original shown in FIG. 7. In FIG. 19, components corresponding to those in the above-described embodiment are denoted by like numerals.

As shown in FIG. 19, the pad electrode PAD and interconnect M1 are in the shape of a comb, face each other, and overlap each other.

While the invention made by the present inventors has been described with reference to the foregoing embodiment, it goes without saying that the present invention is not limited to the embodiment and that various modifications can be made without departing from the gist of the invention.

What is claimed is:

1. A semiconductor device comprising:
a semiconductor substrate having a main surface and a back surface;
a first insulating film formed over the main surface of the semiconductor substrate, and having a first surface in contact with the main surface and a second surface opposed to the first surface;
a polysilicon film disposed over the first insulating film in contact with the second surface of the first insulating film; and
an electrode film disposed adjacent to the first surface of the first insulating film, and being coupled to the polysilicon film,
wherein, the semiconductor substrate has a first opening that passes therethrough from the back surface to the main surface, and exposes the first insulating film,
wherein, the first insulating film has a second opening that is located in the first opening, and exposes a part of the polysilicon film, and
wherein, the electrode film is formed in the second opening, and extends to the first surface of the first insulating film.

2. The semiconductor device according to claim 1, further comprising:
a second insulating film covering the back surface of the semiconductor substrate and the electrode film, and having a third opening that exposes a part of the electrode film,
wherein, the third opening is located inside the first opening and located outside the second opening in plan view.

3. The semiconductor device according to claim 1, further comprising:
an interconnect made of a metal film, disposed above the polysilicon film, and electrically coupled to the polysilicon film.

4. The semiconductor device according to claim 3, further comprising:
a plug electrode made of a metal conductive layer, and coupling the polysilicon film and the interconnect,
wherein, the plug electrode is located outside the second opening in plan view.

5. The semiconductor device according to claim 1, further comprising:
a first semiconductor region of a first conductivity type, and a second semiconductor region of a second conductivity type that is opposite to the first conductivity type; and
a photodiode region formed in the semiconductor substrate.

6. The semiconductor device according to claim 5, comprising:
a light shielding film formed over the back surface of the semiconductor substrate, and having a fourth opening that exposes the photodiode region.

7. The semiconductor device according to claim 6, further comprising:
a color filter disposed to cover the fourth opening; and
a microlens disposed over the color filter.

8. The semiconductor device according to claim 1, further comprising:
an active region formed in the main surface of the semiconductor substrate; and
a transistor formed in the active region, and having a gate electrode, a source region, and a drain region,
wherein, the active region is surrounded by the first insulating film that extends along the main surface of the semiconductor substrate.

9. A method for fabricating a semiconductor device comprising the steps of:
(a) preparing a semiconductor wafer including a semiconductor substrate that has a main surface and a back surface, a first insulating film that is formed over the main surface of the semiconductor substrate and has a first surface in contact with the main surface and a second surface opposed to the first surface, and a polysilicon film that is disposed over the first insulating film in contact with the second surface of the first insulating film;
(b) forming a first opening in the semiconductor substrate from the back surface to reach the first surface of the first insulating film;
(c) forming a second opening in the first insulating film, the second opening being located in the first opening, and reaching the polysilicon film; and
(d) forming an electrode film in the first opening, the electrode film making contact with the polysilicon film in the second opening, and extending to the first surface of the first insulating film.

10. The method for fabricating the semiconductor device according to claim 9, further comprising the steps of:
(e) between the steps (a) and (b), polishing the back surface of the semiconductor substrate; and
(f) between the steps (a) and (b), attaching a support substrate over the main surface of the semiconductor substrate.

11. The method for fabricating the semiconductor device according to claim 9, further comprising the steps of:
(g) after the step (d), forming a second insulating film covering the back surface of the semiconductor substrate and the electrode film, and having a third opening that exposes a part of the electrode film.

12. The method for fabricating the semiconductor device according to claim 11,
wherein, the third opening is formed outside the second opening so that the second insulating film covers the electrode film in the the second opening.

13. The method for fabricating the semiconductor device according to claim 9,
wherein, the semiconductor wafer includes an active region surrounded by the first insulating film, a gate electrode formed over the main surface of the semiconductor substrate in the active layer with a gate insulating film interposed therebetween, and a source region and a drain region formed on opposite ends of the gate electrode, the gate electrode being made of a film that is the same layer as the polysilicon film.

14. The method for fabricating the semiconductor device according to claim 9,
wherein, the semiconductor wafer includes an interconnect composed of a metal film formed above the polysilicon film, and the interconnect is electrically coupled to the polysilicon film.
